(19) United States
(12) Patent Application Publication
(10) Pub. No.: US 2026/0005774 A1
(43) Pub. Date: Jan. 1, 2026

(54) OPERATION VOLTAGE DETECTION METHOD AND COMMUNICATION DEVICE

(71) Applicant: UNIVERSAL SCIENTIFIC INDUSTRIAL ( SHANGHAI ) CO., LTD., SHANGHAI (CN)

(72) Inventors: WEI-CHIA WU, SHANGHAI (CN); GUAN-TING KE, SHANGHAI (CN); WU-CHIEH LIN, SHANGHAI (CN); CHUN-HUANG LEE, SHANGHAI (CN)

(21) Appl. No.: 19/009,458

(22) Filed: Jan. 3, 2025

(30) Foreign Application Priority Data
Jun. 27, 2024 (CN) 202410852480.8

(51) Int. Cl. H04B 17/00; G01R 31/28

(52) U.S. Cl. CPC H04B 17/0085; G01R 31/2834

(57) ABSTRACT

An operation voltage method and a communication are provided. The operation voltage detection method is configured to use a test apparatus or a test program to detect a plurality of operation voltages of a power amplification circuit in a device under test. The power amplification circuit includes a plurality of gain modes. Each of the gain modes includes a plurality of operation frequency bands. Each of the operation frequency bands includes a plurality of operation voltage intervals. The operation voltage detection method detects each test passing voltage of each of the plurality of operation voltage intervals of each of operation frequency bands of each of the gain modes.

### CROSS-REFERENCE TO RELATED PATENT APPLICATION

This application claims the benefit of priority to Patent Application No. 202410852480.8, filed on Jun. 27, 2024, in the People's Republic of China. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to an operation voltage detection method and a communication device, and more particularly to an operation voltage detection method and a communication device with low power consumption.

### BACKGROUND OF THE DISCLOSURE

The operation voltage of the power amplification circuit in the existing communication circuit is determined based on the output power of the power amplification circuit, and the same and fixed operation voltage is mostly provided in different operation modes. As a result, the power consumption of the power amplification circuit cannot be effectively reduced.

When the power amplification circuit is in operation, even if the voltage of the power supply changes, the power amplification circuit will consume the same current at a given output power. In order to maintain the linear characteristics of the power amplification circuit, a higher power supply voltage is required to obtain a higher output power level. If the voltage of the power amplification circuit is fixed, the voltage can only be set at a peak value to meet the linear requirement of the maximum transmit power, thus a lot of power is consumed.

### SUMMARY OF THE DISCLOSURE

In response to the above-referenced technical inadequacies, the present disclosure provides an operation voltage detection method and a communication device.

In order to solve the above-mentioned problems, one of the technical aspects adopted by the present disclosure is to provide an operation voltage detection method. The operation voltage detection method is configured to use a test apparatus or a test program to detect a plurality of operation voltages of a power amplification circuit in a device under test. The power amplification circuit includes a plurality of gain modes. Each of the gain modes includes a plurality of operation frequency bands. Each of the operation frequency bands includes a plurality of operation voltage intervals. The operation voltage detection method includes: implementing step A, which includes: providing a first predetermined voltage, and setting the first predetermined voltage to an initial operation voltage of the plurality of operation voltage intervals in one of the plurality of operation frequency bands; step B: performing a test procedure on a first operation voltage interval of the plurality of operation voltage intervals of the power amplification circuit based on the first predetermined voltage to generate a plurality of test results, and determining whether or not to increase the first operation voltage by one or more predetermined voltage intervals based on the plurality of test results until all of the plurality of test results of the first operation voltage interval pass the test procedure to obtain a corresponding first test passing voltage; step C: setting the first test passing voltage to the initial operation voltage of remaining ones of the plurality of operation voltage intervals; step D: sequentially performing the test procedures of the remaining ones of the plurality of the operation voltage intervals based on the newly set initial operation voltage to obtain a plurality of test passing voltages corresponding to the remaining ones of the plurality of operation voltage intervals of one of the plurality of operation frequency bands; step E: repeating step A to step D to obtain a plurality of test passing voltages for each of remaining ones of the plurality of operation frequency bands of the power amplification circuit; and step F: establishing an average voltage tracking characterization table based on the plurality of test passing voltages of each of the plurality of operation frequency bands.

In order to solve the above-mentioned problems, another one of the technical aspects adopted by the present disclosure is to provide a communication device. The communication device includes a power amplification circuit and a control circuit. The power amplification circuit includes a plurality of gain modes. Each of the plurality of the gain modes includes a plurality of operation frequency bands. Each of the plurality of operation frequency bands includes a plurality of the operation voltage intervals. The control circuit is connected to the power amplification circuit. An average voltage tracking characterization table is established based on the following steps. The steps include: implementing step A, which includes: providing a first predetermined voltage, and setting the first predetermined voltage to an initial operation voltage of the plurality of operation voltage intervals in one of the plurality of operation frequency bands; step B: performing a test procedure on a first operation voltage interval of the plurality of operation voltage intervals of the power amplification circuit based on the first predetermined voltage to generate a plurality of test results, and determining whether or not to increase the first operation voltage by one or more predetermined voltage intervals based on the plurality of test results until all of the plurality of test results of the first operation voltage interval pass the test procedure to obtain a corresponding first test passing voltage; step C: setting the first test passing voltage to the initial operation voltage of remaining ones of the plurality of operation voltage intervals; step D: sequentially performing the test procedures of the remaining ones of the plurality of the operation voltage intervals based on the newly set initial operation voltage to obtain a plurality of test passing voltages corresponding to the remaining ones of the plurality of operation voltage intervals of one of the plurality of operation frequency bands; step E: repeating step A to step D to obtain a plurality of test passing voltages for each of remaining ones of the plurality of operation frequency bands of the power amplification circuit; and step F: establishing an average voltage tracking characterization table based on the plurality of test passing voltages of each of the plurality of operation frequency bands.

Therefore, the operation voltage detection method and communication device provided by the present disclosure can effectively detect the operation voltage of the power amplification circuit in different operation voltage intervals, such that the power consumption of the power amplification circuit can be reduced. Therefore, the service time of the battery unit in the device under test or the communication device can be effectively extended.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a flowchart of using a software tool to detect an operation voltage of a power amplification circuit;

FIG. 2 is a flowchart of an operation voltage detection method according to a first embodiment of the present disclosure;

FIG. 3A and FIG. 3B are another flowchart of the operation voltage detection method according to the first embodiment of the present disclosure; and

FIG. 4 is a schematic view of a communication device according to a second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

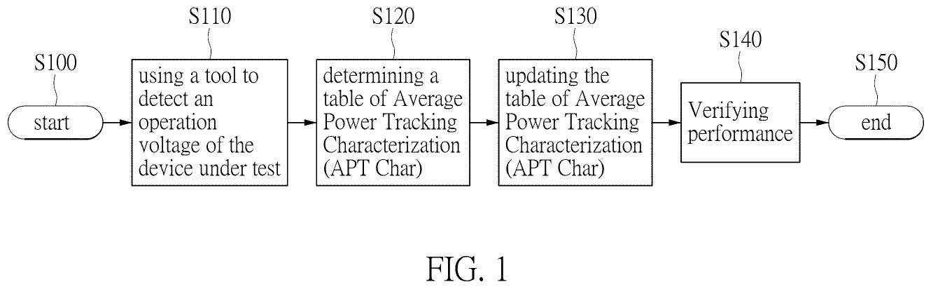

Referring to FIG. 1, FIG. 1 is a flowchart of using a software tool to detect an operation voltage of a power amplification circuit.

From step S100 to step S150, software tools or hardware test tools are used to detect a plurality of operation voltage intervals of multiple operation frequency bands of the power amplification circuit (PA) in the device under test (DUT).

Step S100 and step S150 are respectively a beginning and an end of the detection method. Steps S110 to S140 are as the following.

Step S110 includes: using a tool to detect an operation voltage of the device under test.

Step S120 includes: determining an average power tracking characterization (APT Char) table.

Step S130 includes: updating the average power tracking characterization (APT Char) table.

Step S140 includes: verifying performance.

In addition, in this embodiment, the device under test can be used by a signaling mode, such that the device under test is detected, and the operation voltage of the device under test is tested.

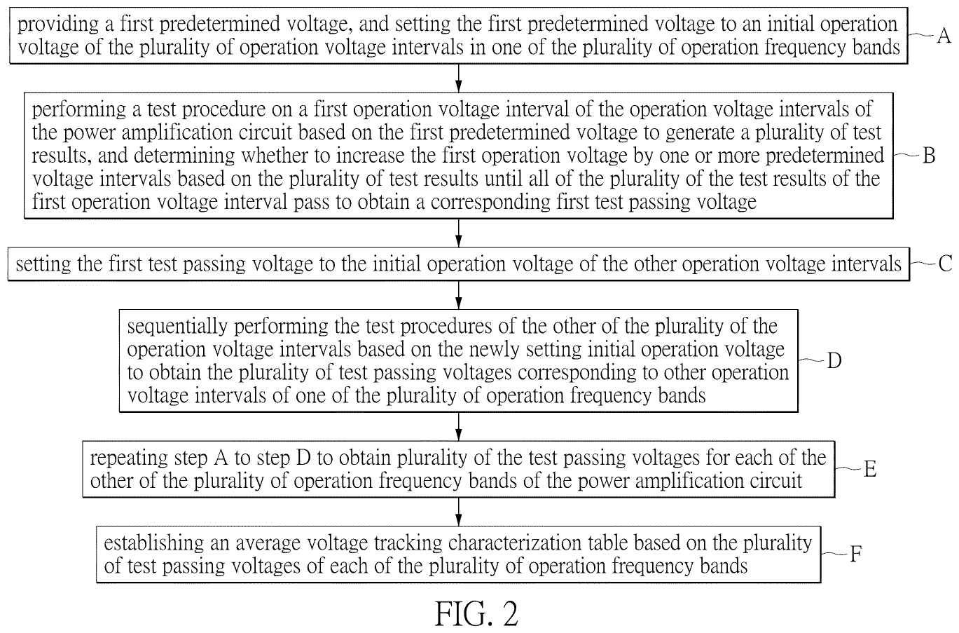

Referring to FIG. 2, FIG. 2 is a flowchart of an operation voltage detection method according to a first embodiment of the present disclosure.

In this embodiment, an operation voltage detection method is provided. The operation voltage detection method uses a test apparatus or a test program to detect a plurality of operation voltages of a power amplification circuit (PA) of a device under test (DUT). The power amplification circuit includes a plurality of operation frequency bands. Each of the operation frequency bands includes a plurality of operation voltage intervals. The operation voltage detection method includes the following steps.

Step A includes: providing a first predetermined voltage, and setting the first predetermined voltage to an initial operation voltage of the plurality of operation voltage intervals in one of the plurality of operation frequency bands.

Step B includes: performing a test procedure on a first operation voltage interval of the plurality of operation voltage intervals of the power amplification circuit based on the first predetermined voltage to generate a plurality of test results, and determining whether or not to increase the first operation voltage by one or more predetermined voltage intervals based on the plurality of test results until all of the plurality of test results of the first operation voltage interval pass the test procedure to obtain a corresponding first test passing voltage.

Step C includes: setting the first test passing voltage to the initial operation voltage of remaining ones of the plurality of operation voltage intervals.

Step D includes: sequentially performing the test procedures of the remaining ones of the plurality of the operation voltage intervals based on the newly set initial operation voltage to obtain a plurality of test passing voltages corresponding to the remaining ones of the plurality of operation voltage intervals of one of the plurality of operation frequency bands.

Step E includes: repeating step A to step D to obtain a plurality of test passing voltages for each of remaining ones of the plurality of operation frequency bands of the power amplification circuit.

Step F includes: establishing an average voltage tracking characterization table based on the plurality of test passing voltages of each of the plurality of operation frequency bands.

In addition, before step A, a gain mode is firstly selected. For example, a gain mode 2 is selected as an initial testing base for steps A to F. In the test procedure, each of the operation frequency bands of each of the gain modes is tested.

After completing the test passing voltage of all operation frequency bands of the gain mode 2 and each of the operation voltage intervals in each of the operation frequency bands, another gain mode can be selected for testing.

In the above steps, the plurality of operation voltage intervals are determined based on a plurality of output powers of the power amplification circuit (i.e., a power amplifier, PA). That is to say, the power amplification circuit can output multiple different output powers (power level) in different operation frequency bands. In this embodiment, the first predetermined voltage is 700 mV. In other embodiments, the first predetermined voltage can be adjusted according to actual requirements.

Furthermore, the predetermined voltage interval in this embodiment is 100 mV. In other embodiments, the predetermined voltage interval may be 50 mV or other voltage intervals, such as 70 mV, 80 mV, 150 mV or 200 mV, which is not limited in the present disclosure.

In addition, steps A to D will sequentially test the power (power level) of plurality of operation voltage intervals in each operation frequency band of the power amplification circuit from small to large, and obtain each of the test passing voltages for each of the operation voltage intervals.

That is, the test passing voltage of each of the operation voltage intervals is tested by gradually increasing the first predetermined voltage by a plurality of predetermined voltage intervals. The difference between each of the test passing voltages and the first predetermined voltage is N times the predetermined voltage interval. N is greater than or equal to 0, and N is an integer. In addition, the average voltage tracking characterization table (APT Char) is used to show the combined relationship between the bias voltage (PA bias) and the quiescent operation current (ICQ) of the power amplification circuit in power level (e.g., 15 dBm to 26 dBm) in each of operation frequency bands (band) of the power amplification circuit in different gain modes and each of the operation voltage intervals.

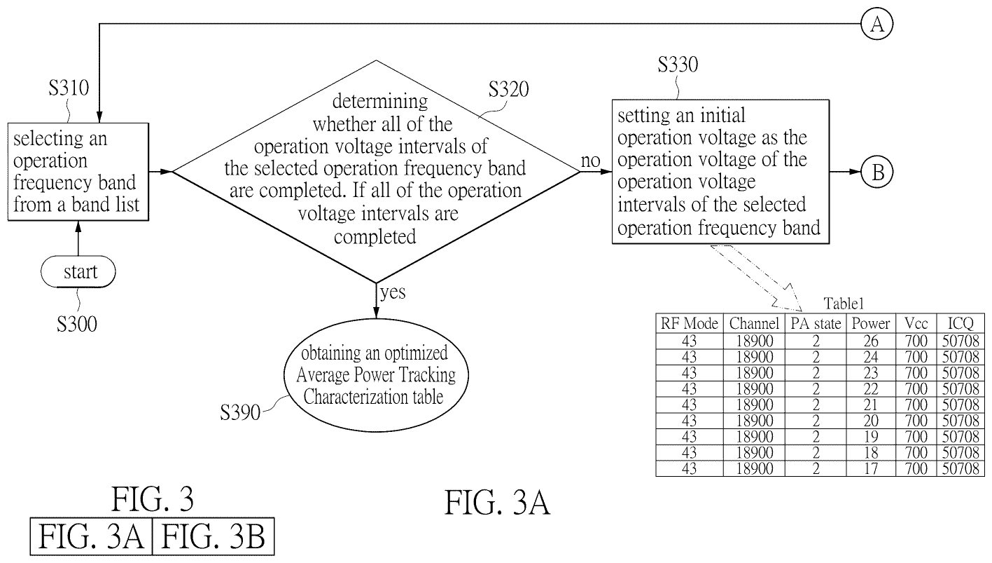

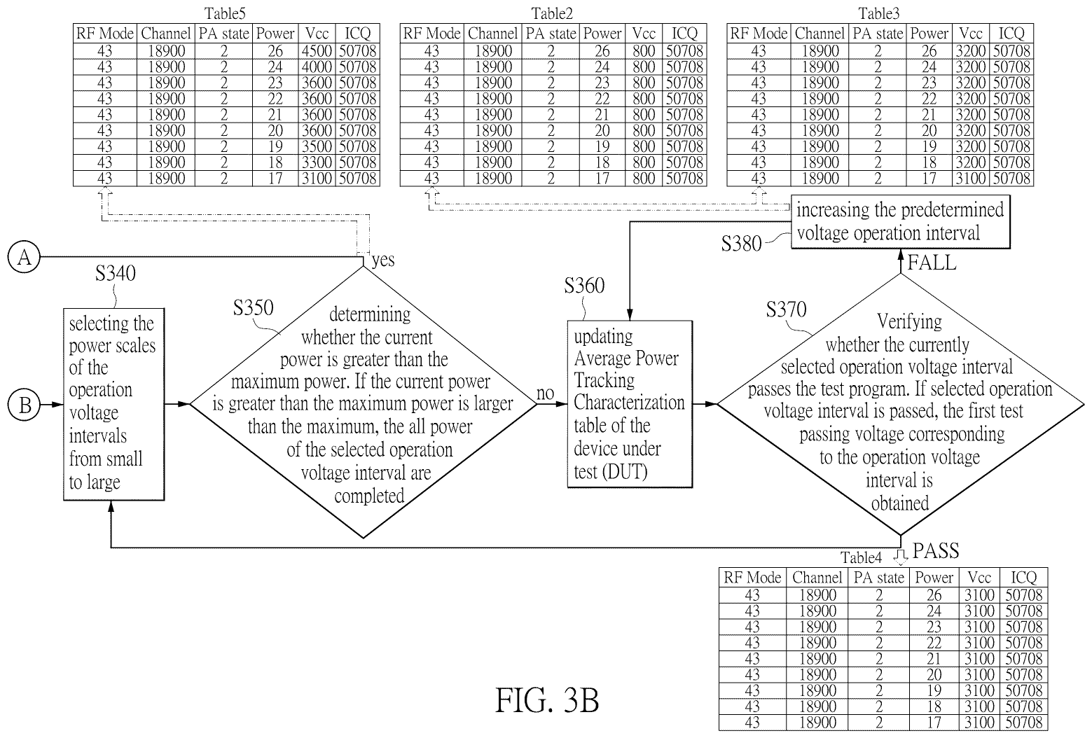

Referring to FIG. 3A and FIG. 3B, FIG. 3A and FIG. 3B are another flowchart of the operation voltage detection method according to the first embodiment of the present disclosure.

The flowchart in FIG. 3 includes the following steps.

Step S300 includes: starting the procedure.

Step S310 includes: selecting an operation frequency band from a band list.

Step S320 includes: determining whether all of the operation voltage intervals of the selected operation frequency band are completed. If all of the operation voltage intervals are completed, step S390 is executed, and if false, step S330 is executed.

Step S330 includes: setting an initial operation voltage as the operation voltage of the operation voltage intervals of the selected operation frequency band.

Step S340 includes: selecting the power levels of the operation voltage intervals from small to large.

Step S350 includes: determining whether the current power is greater than the maximum power. If the current power is greater than the maximum power, all power of the selected operation voltage interval are completed, and if false, step S360 is executed.

Step S360 includes: updating an average power tracking characterization table of the device under test (DUT).

Step S370 includes: verifying whether the currently selected operation voltage interval passes the test procedure. If the selected operation voltage interval passes the test procedure, the first test passing voltage corresponding to the operation voltage interval is obtained, and then step S340 is executed, and if false, step S380 is executed.

Step S380 includes: increasing the predetermined voltage operation interval.

Step S390 includes: obtaining an optimized average power tracking characterization table.

Referring to FIG. 3, a plurality of tables of the operation voltage intervals are shown adjacent to the multiple steps to respectively represent the adjustment of the operation voltage in the multiple steps. For example, Table 1 corresponds to step S330 that sets the operation voltage in the operation voltage intervals of all power levels in the selected operation frequency band to the initial operation voltage of 700 mV. Table 5 corresponding to the completion of step S350 is an average voltage tracking characterization table indicating that the current operation voltage interval is completed. In addition, FIG. 3 is a flowchart performed after a gain mode of the power amplification circuit is selected.

Since step S380 is a subsequent step after the verification failure (Fail) of step S370, the two tables corresponding to step S380 are Table 2 and Table 3 that are adjusted following Table 1. Table 2 on the left is a test procedure with the lowest power level (a power of 17 dBm) using an initial operation voltage of 700 mV. When the test procedure fails (Fail), a predetermined voltage interval (100 mV) will be added. That is, after increasing the predetermined voltage interval (100 mV) on the basis of the initial operation voltage of 700 mV, the test procedure is continued with the operation voltage of 800 mV. Table 3 shows that the test is performed with 3100 mV as the operation voltage and the test failed. Based on the previous test passing voltage of 3100 mV, after increasing by the predetermined voltage range (100 mV), the subsequent test was conducted with 3200 mV as the operation voltage. That is, Table 3 on the right represents that the first sequence of power levels (the lowest power from small to large) (a power of 17 dBm) passes the test program with an operation voltage of 3100 mV, and then the second sequence of the test procedure for power level (a power of 18 dBm) will be tested with 3100 mV as the operation voltage. However, Table 3 shows that the second sequential power level (a power of 18 dBm) does not pass the test procedure with 3100 mV as the operation voltage. Therefore, based on the operation voltage of 3100 mV, a predetermined voltage interval (100 mV) is added, and the second sequence of the test procedure for power level (a power of 18 dBm) is tested with 3200 mV as the operation voltage.

In step S370, 3100 mV is used as the operation voltage and the corresponding table for the test procedure verification success (PASS) is Table 4, indicating that the lowest power level of the test procedure (a power of 17 dBm) in the selected operation voltage interval needs to pass the test procedure with 3100 mV as the operation voltage. Therefore, newly set voltage of the operation voltages of all operation voltage intervals in the average voltage tracking characterization table is 3100 mV, and then the method returns to step S340 to select the operation voltage interval with the second lowest power (a power of 18 dBm) to continue the test procedure. In this embodiment, the test procedure is an adjacent channel leakage ratio procedure (ACLR).

### Second Embodiment

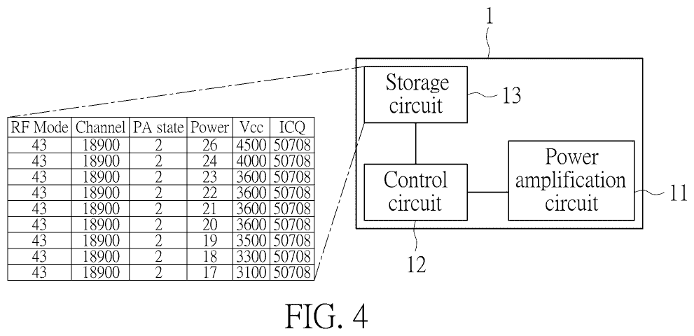

Referring to FIG. 4, FIG. 4 is a schematic view of a communication device according to a second embodiment of the present disclosure.

In this embodiment, a communication device 1 is provided. The communication device 1 at least includes a power amplification circuit 11, a control circuit 12, and a storage circuit 13. The control circuit 12 is electrically connected to the power amplification circuit 11 and the storage circuit 13. The power amplification circuit 11 includes a plurality of gain modes. Each of the gain modes of the power amplification circuit 11 includes a plurality of operation frequency bands, and each of the operation frequency bands includes a plurality of operation voltage intervals.

The control circuit 12 respectively provides a test passing voltage in the plurality of operation voltage intervals of the plurality of operation frequency bands to the power amplification circuit 11 based on an average voltage tracking characterization table in the storage circuit 13. That is, the plurality of test passing voltages of the plurality of operation voltage intervals of the plurality of operation frequency bands are variable.

A difference between the test pass voltages of the multiple operation voltage intervals of the plurality of operation frequency bands is N times the predetermined voltage interval. N is greater than or equal to zero, and N is an integer.

In this embodiment, the predetermined voltage interval is 100 mV. In addition, the average voltage tracking characterization table is established according to the method of steps A to F and steps S310 to S390 in the first embodiment, and details thereof are not reiterated herein.

### Beneficial Effects of the Embodiments

In conclusion, the operation voltage detection method and communication device provided by the present disclosure can effectively detect the operation voltage of the power amplification circuit in different operation voltage intervals, such that the power consumption of the power amplification circuit can be reduced. Therefore, the service time of the battery unit in the device under test or the communication device can be effectively extended.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An operation voltage detection method, being configured to use a test apparatus or a test program to detect a plurality of operation voltages of a power amplification circuit in a device under test, the power amplification circuit including a plurality of gain modes, each of the gain modes including a plurality of operation frequency bands, and each of the operation frequency bands including a plurality of operation voltage intervals; and the operation voltage detection method comprising:
implementing step A, which includes: providing a first predetermined voltage, and setting the first predetermined voltage to an initial operation voltage of the plurality of operation voltage intervals in one of the plurality of operation frequency bands;
step B: performing a test procedure on a first operation voltage interval of the plurality of operation voltage intervals of the power amplification circuit based on the first predetermined voltage to generate a plurality of test results, and determining whether or not to increase the first operation voltage by one or more predetermined voltage intervals based on the plurality of test results until all of the plurality of test results of the first operation voltage interval pass the test procedure to obtain a corresponding first test passing voltage;
step C: setting the first test passing voltage to the initial operation voltage of remaining ones of the plurality of operation voltage intervals;
step D: sequentially performing the test procedures of the remaining ones of the plurality of the operation voltage intervals based on the newly set initial operation voltage to obtain a plurality of test passing voltages corresponding to the remaining ones of the plurality of operation voltage intervals of one of the plurality of operation frequency bands;
step E: repeating step A to step D to obtain a plurality of test passing voltages for each of remaining ones of the plurality of operation frequency bands of the power amplification circuit; and
step F: establishing an average voltage tracking characterization table based on the plurality of test passing voltages of each of the plurality of operation frequency bands.

2. The operation voltage detection method according to claim 1, wherein, before implementing step A, one of the plurality of gain modes of the power amplification circuit is selected.

3. The operation voltage detection method according to claim 2, wherein the plurality of operation voltage intervals are determined based on a plurality of output powers of the power amplification circuit.

4. The operation voltage detection method according to claim 3, wherein step A to step D are sequentially implemented according to a power level of the plurality of operation voltage intervals in each of the operation frequency bands from small to large, and the test passing voltage for each of the plurality of operation voltage intervals is obtained.

5. The operation voltage detection method according to claim 1, wherein the first predetermined voltage is 700 mV, and the predetermined voltage interval is 100 mV.

6. The operation voltage detection method according to claim 1, wherein a difference between the first test passing voltage of the first operation voltage interval and the initial operation voltage is N times the predetermined voltage interval, N is greater than or equal to 0, and N is an integer.

7. The operation voltage detection method according to claim 1, wherein the test procedure is an adjacent channel leakage ratio (ACLR) procedure.

8. A communication device, comprising:
a power amplification circuit including a plurality of gain modes, wherein each of the plurality of gain modes includes a plurality of operation frequency bands, and each of the plurality of operation frequency bands includes a plurality of operation voltage intervals; and
a control circuit being connected to the power amplification circuit, wherein an average voltage tracking characterization table is established based on the operation voltage detection method as claimed in claims 1 to 7;
wherein, a difference between the first test passing voltage of the first operation voltage interval and the initial operation voltage is N times of the predetermined voltage intervals, N is greater than or equal to 0, and N is an integer.
